(19) United States
(12) Patent Application Publication
(10) Pub. No.: US 2026/0214800 A1
(43) Pub. Date: Jul. 23, 2026

(54) CIRCUIT BOARD AND MANUFACTURING METHOD THEREOF

(71) Applicant: SAMSUNG ELECTRO-MECHANICS CO., LTD., Suwon-si (KR)

(72) Inventors: Yangje Lee, Suwon-si (KR); Changgon Kim, Suwon-si (KR); Seungju Lee, Suwon-si (KR); Sumin Seo, Suwon-si (KR); Changsoo Choi, Suwon-si (KR); Yeonji Kim, Suwon-si (KR); Gyeongah Yun, Suwon-si (KR); Kyehwan Ahn, Suwon-si (KR)

(73) Assignee: SAMSUNG ELECTRO-MECHANICS CO., LTD., Suwon-si (KR)

(21) Appl. No.: 19/279,549

(22) Filed: Jul. 24, 2025

(30) Foreign Application Priority Data
Jan. 20, 2025 (KR) 10-2025-0008307

(51) Int. Cl. H05K 1/11; H05K 1/03; H05K 3/00; H05K 3/24

(52) U.S. Cl. CPC H05K 1/116; H05K 1/0306; H05K 3/0017; H05K 3/241; H05K 2201/09481; H05K 2201/096; H05K 2201/09618

(57) ABSTRACT

A printed circuit board includes an insulating layer having a via hole penetrating in a first direction, and a through via that fills the via hole and includes a hollow portion penetrating in the first direction. A plug fills the hollow portion of the through via. A circuit layer is disposed on the insulating layer and the through via. The through via includes a penetrating portion extending in the first direction and an extending portion that branches from the penetrating portion in a direction perpendicular to the first direction and is disposed on the insulating layer. The circuit layer includes a pad disposed on the extending portion and a circuit wiring disposed on the insulating layer.

### CROSS-REFERENCE TO RELATED APPLICATION

This application claims priority to and the benefit of Korean Patent Application No. 10-2025-0008307 filed with the Korean Intellectual Property Office on Jan. 20, 2025, the entire contents of which are incorporated herein by reference.

### BACKGROUND OF THE INVENTION

### (a) Field of the Invention

The present disclosure relates to a circuit board and a manufacturing method thereof.

### (b) Description of the Related Art

As electronic devices in the IT field, including mobile phones, become lighter, thinner, shorter, and smaller, the circuit integration density is increasing and the number of integrated circuits for input/output is increasing, so the width of circuit patterns applied to printed circuit boards for package is becoming miniaturized.

Reducing line width and space is a core technology for wiring fine circuits. However, the thickness of the circuit pattern is increasing, and it is difficult to miniaturize the circuits due to process-related reasons such as forming circuit patterns by plating and etching.

### SUMMARY OF THE INVENTION

The present disclosure attempts to provide a circuit board and a manufacturing method thereof capable of reducing circuit design constraints and forming a fine circuit pattern.

However, the problem to be solved by embodiments of the present disclosure is not limited to the above-described problems and can be variously extended within the scope of the technical concept included in the present disclosure.

A circuit board according to an embodiment may include an insulating layer having a via hole penetrating in the first direction, a through via extending to fill the via hole and having a hollow portion penetrating in the first direction, a plug disposed to fill the hollow portion of the through via, and a circuit layer disposed on the insulating layer and the through via. The through via may include a penetrating portion extending in the first direction and an extending portion extending from the penetrating portion in a direction perpendicular to the first direction and disposed on the insulating layer. The circuit layer may include a pad disposed on the extending portion and a circuit wiring disposed on the insulating layer.

The circuit layer may include an electroless plating layer disposed on the through via and the insulating layer, and an electro-plating layer disposed on the electroless plating layer.

A portion of the electroless plating layer disposed on the through via may be disposed to cover at least a side surface of the extending portion.

A portion of the electroless plating layer disposed on the through via may be disposed along an outer circumferential surface of the extending portion.

The pad may include a first pad seed layer pattern, the extending portion of the through via, a second pad seed layer pattern, and a first pad electro-plating layer pattern sequentially stacked on the insulating layer.

The circuit wiring may include a second circuit seed layer pattern, and a first circuit electro-plating layer pattern.

The thickness of the first circuit electro-plating layer pattern may be greater than that of the first pad electro-plating layer pattern.

A first pad copper foil layer pattern may be disposed between the insulating layer and the first pad seed layer pattern in the first direction.

The second pad seed layer pattern may be disposed to have a step at one end.

The first pad electro-plating layer pattern may be disposed to have a step at one end.

The plug may extend to protrude from a surface of the insulating layer.

The plug may be non-conductive

The insulating layer may include a core portion and a primer layer stacked on opposite both sides of the core portion.

The insulating layer may be a glass core.

A manufacturing method of a circuit board according to an embodiment may include stacking a copper foil on a surface of an insulating layer to form a copper foil layer, forming a via hole to penetrate the insulating layer and the copper foil layer, plating on the copper foil layer and an inner wall of the via hole to form a through via forming portion, forming a plug to fill an inner space of the through via forming portion, forming a first mask pattern at a region disposed along an edge of the via hole on the through via forming portion, etching an exposed portion by the first mask pattern to form a through via, forming a second mask pattern to expose a region disposed on the through via and the plug, and a region disposed on a portion of the insulating layer spaced apart from the region, and forming a circuit layer by plating on the regions exposed by the second mask pattern.

A first seed layer may be formed by electroless plating on a surface of the insulating layer in which the via hole is formed. Forming the through via forming portion may include electro-plating on the first seed layer to form the through via forming portion.

Forming the circuit layer may include plating on the regions exposed by the second mask pattern to have a step with a portion of the through via disposed on the insulating layer.

A manufacturing method of a circuit board according to another embodiment may include forming a via hole to penetrate an insulating layer, forming a third mask pattern on the insulating layer to expose a region disposed along an edge of the via hole, plating along the exposed region and an inner wall of the via hole to form a through via, forming a plug to fill a inner space of the through via, forming a fourth mask pattern to expose a region disposed on the through via and the plug, and a region disposed on a portion of the insulating layer, and plating on the regions exposed by the fourth mask pattern to form a circuit layer.

Forming the circuit layer may include forming an electroless plating layer and forming an electro-plating layer on the electroless plating layer.

The method may further include forming a core portion, and stacking a primer layer on opposite both sides of the core portion to form the insulating layer.

The insulating layer may include a glass core.

A copper foil layer may be formed by stacking a copper foil on a surface of the insulating layer and

The copper foil layer may be removed by etching.

According to the embodiments of the circuit board and the manufacturing method thereof, circuit design constraints due to metal thicknesses of circuit layers may be reduced, and circuit patterns may be miniaturized.

### BRIEF DESCRIPTION OF THE DRAWINGS

FIG. 1 is a cross-sectional view schematically illustrating a circuit board according to an embodiment.

FIG. 2 is an enlarged cross-sectional view of portion A of the circuit board illustrated in FIG. 1.

FIG. 3 to FIG. 14 are cross-sectional views illustrating a manufacturing method of a circuit board according to an embodiment.

FIG. 15 is a cross-sectional view schematically illustrating a circuit board according to another embodiment.

FIG. 16 is an enlarged cross-sectional view of portion B of the circuit board illustrated in FIG. 15.

FIG. 17 is a cross-sectional view schematically illustrating a circuit board according to yet another embodiment.

FIG. 18 is an enlarged cross-sectional view of portion C of the circuit board illustrated in FIG. 17.

FIG. 19 to FIG. 29 are cross-sectional views illustrating a manufacturing method of a circuit board according to yet another embodiment.

FIG. 30 is a cross-sectional view schematically illustrating a circuit board according to yet another embodiment.

FIG. 31 is an enlarged cross-sectional view of portion D of the circuit board illustrated in FIG. 30.

FIG. 32 is a cross-sectional view for explaining the manufacturing method of the circuit board illustrated in FIG. 30.

FIG. 33 is a cross-sectional view schematically illustrating a circuit board according to yet another embodiment.

FIG. 34 is a cross-sectional view for explaining the manufacturing method of the circuit board illustrated in FIG. 33.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification. In addition, some elements in the accompanying drawings are exaggerated, omitted, or schematically illustrated, and the size of each component does not fully reflect the actual size.

The accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

Terms including ordinal numbers such as first, second, and the like will be used only to describe various components and are not to be interpreted as limiting these components. The terms are only used to differentiate one component from other components.

Furthermore, it will be understood that when an element such as a layer, film, region, or substrate is referred to as being “on” another element, it can be directly on the other element or intervening elements may also be present. On the contrary, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

It will be further understood that terms “comprises/includes” or “have” used throughout the specification specify the presence of stated features, numerals, steps, operations, elements, parts, or a combination thereof, but do not preclude the presence or addition of one or more other features, numerals, steps, operations, elements, parts, or a combination thereof. Accordingly, unless explicitly described to the contrary, the word “comprise” and variations such as “comprises” or “comprising” will be understood to imply the inclusion of stated components but not the exclusion of any other components.

Furthermore, throughout the specification, the phrase “in a plan view” means when an object portion is viewed from above, and the phrase “in a cross-sectional view” means when a cross-section taken by vertically cutting an object portion is viewed from the side.

Throughout the specification, “connected” means that two or more elements are not only directly connected, but two or more elements may be connected indirectly through other elements, physically connected as well as being electrically connected, or it may be referred to by different names depending on the location or function but may mean integral.

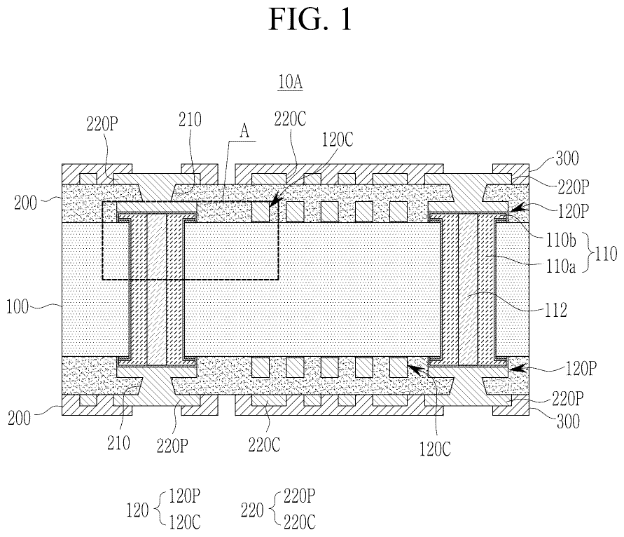

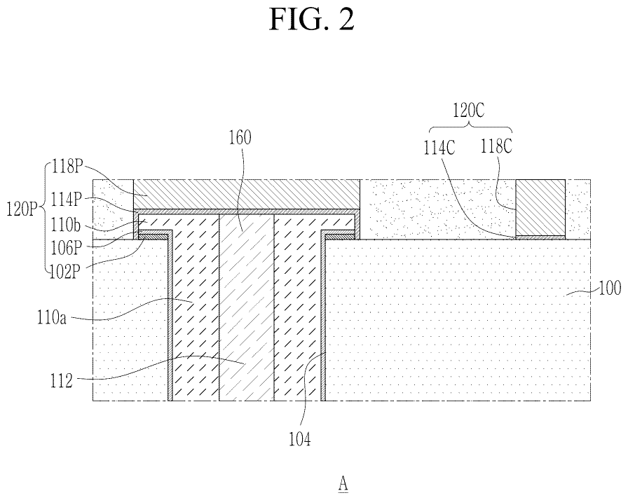

Hereinafter, A circuit board 10A according to an embodiment will be described with reference to FIG. 1 and FIG. 2.

FIG. 1 is a cross-sectional view schematically illustrating a circuit board according to the embodiment. FIG. 2 is an enlarged cross-sectional view of portion A of the circuit board illustrated in FIG. 1.

Referring to FIG. 1 and FIG. 2, the circuit board 10A according to the embodiment may include a first insulating layer 100 provided as a core layer. A first circuit layer 120 may be disposed on both surface of the first insulating layer 100, and the first circuit layer 120 may include a first pad 120P and a first circuit wiring 120C. The first pad 120P may be disposed on an extending portion 110b, and the first circuit wiring 120C may be disposed on the first insulating layer 100.

A second insulating layer 200 may be disposed on the first insulating layer 100 to cover the first circuit wiring 120. A second circuit layer 220 including a second pad 220P and a second circuit wiring 220C may be disposed on the second insulating layer 200. The second pad 220P may be connected to the first pad 120P through a build up via 210 penetrating the second insulating layer 200.

A passivation layer 300 may be disposed on the second insulating layer 200. The passivation layer 300 may protect the internal components from external physical and chemical damage or the like. The passivation layer 300 may cover a surface of the second insulating layer 200 and expose at least a portion of the second pad 220P. The passivation layer 300 may be made of a photosensitive resin, and may be, for example, a solder resist layer.

The first insulating layer 100 and the second insulating layer 200 may include an insulating material. The insulating material may include a thermosetting resin such as an epoxy resin, a thermoplastic resin such as polyimide, or these resins containing an inorganic filler such as silica and a reinforcing material such as glass fiber. The insulating material may be a photosensitive material or a non-photosensitive material. For example, solder resist (SR), ajinomoto-build up film (ABF), FR-4, Bismaleimide Triazine (BT), resin coated copper (RCC) or copper clad laminate (CCL), etc. may be used as the insulating material, but are not limited thereto. The insulating material may include a polymer material. For example, a prepreg may be used, but is not limited thereto. In addition, in FIG. 1 and FIG. 2, the first insulating layer 100 is illustrated as one layer, but it is not limited thereto, and a plurality of thin layers may be stacked to constitute the first insulating layer 100.

Each of the first and second circuit layers 120 and 220 may transmit a signal inside the circuit board 10A. A metal material may be used as a material of each of the first and second circuit layers 120 and 220. The metal material may include copper (Cu), aluminum (Al), silver (Ag), tin (Sn), gold (Au), nickel (Ni), lead (Pb), titanium (Ti), or an alloy thereof. Each of the first and second circuit layers 120 and 220 may perform various functions according to a design such as a ground pattern, a power pattern, a signal pattern, and the like. Each of these patterns may have a line shape, a plane shape, or a pad shape. In the case of a circuit layer disposed on the outermost layer among a plurality of circuit layers, it may function as a pad for connection with other substrates or components. The first circuit layer 120 may include an electroless plating layer disposed on a through via 110 and the first insulating layer 100, and an electro-plating layer disposed on the electroless plating layer. The second circuit layer 120 may include an electroless plating layer disposed on the second insulating layer 200 and a build up via 210, and an electro-plating layer disposed on the electroless plating layer.

The first insulating layer 100 may have a via hole 104 penetrating in a first direction. The first direction may be a stacking direction. The through via 110 has a hollow portion penetrating in the first direction and may extend to fill the via hole 104. A plug 112 may fill the hollow portion of the through via 110 and protrude outward from the surface of the first insulating layer 100. The through via 100 may include a penetrating portion 110a extending in the first direction to cover an inner wall of the via hole 104, and the extending portion 110b extending from both ends of the penetrating portion 110a in a direction perpendicular to the first direction and surrounding the plug 112 of a portion protruding to the outside of the surface of the first insulating layer 100. The extending portion 110b may be disposed on the first insulating layer 100. The first pad 120P on both surfaces of the first insulating layer 100 may be connected to each other by the trough via 110.

A metal material may be used as a material of each of the through via 110 and the build up via 210. The metal material may include copper (Cu), aluminum (Al), silver (Ag), tin (Sn), gold (Au), nickel (Ni), lead (Pb), titanium (Ti), or an alloy thereof. Each of the through via 110 and the build up via 210 may include a signal via, a ground via, a power via, and the like according to a design.

The plug 112 may include an insulating plugging ink. The plug 112 may fill an empty space in the via hole 104 to prevent oxidation of the through via 110.

Hereinafter, referring to FIG. 1 and FIG. 2, the first pad 120P and the first circuit wiring 120C of the circuit board 10A according to the embodiment will be described in more detail.

Referring to FIG. 1 and FIG. 2, the first pad 120P and the first circuit wiring 120C may be disposed on the first insulating layer 100 and may have different layer structures.

The first pad 120P may include a first pad copper foil layer pattern 102P and a first pad seed layer pattern 106P interposed between the extending portion 110b of the through via 110 and the first insulating layer 100 and sequentially stacked on the first insulating layer 100 in the first direction. Furthermore, the first pad 120P may include a second pad seed layer pattern 114P and a first pad electro-plating layer pattern 118P sequentially stacked on the extending portion 110b. The second pad seed layer pattern 114P may cover a top surface of the extending portion 110b. In some cases, a portion of the second pad seed layer pattern 114P may cover the top surface of the extending portion 110b and may cover at least a portion of a side surface of the extending portion 110b. In addition, a portion of the second pad seed layer pattern 114P may be disposed along an outer circumferential surface of the extending portion 110b.

As described later, the first pad seed layer pattern 106P and the second pad seed layer pattern 114P may be a metal layer formed by electroless plating, for example, a Cu layer. In addition, the extending portion 110b and the first pad electro-plating layer pattern 118P may be a metal layer formed on the first pad seed layer pattern 106P and the second pad seed layer pattern 114P by electroplating, for example, a Cu layer.

On the other hand, the first circuit wiring 120C may include a second circuit seed layer pattern 114C and a first circuit electro-plating layer pattern 118C sequentially stacked on the first insulating layer 100. The second circuit seed layer pattern 114C may be a metal layer formed by electroless plating, for example, a Cu layer. In addition, the first circuit electro-plating layer pattern 118C may be a metal layer formed on the second circuit seed layer pattern 114C by electro-plating, for example, a Cu layer.

The first pad 120P may include two electro-plating layers, the extending portion 110b and the first pad electro-plating layer pattern 118P, and one electroless plating layer, the second pad seed layer pattern 114P, interposed therebetween. On the other hand, the first circuit wiring 120C may include one electroless plating layer, the second circuit seed layer pattern 114C, and one electro-plating layer, the first circuit electro-plating layer pattern 118C.

The first pad 120P and the first circuit wiring 120C may have substantially the same thickness, however as described later, the first pad electro-plating layer pattern 118P and the first circuit electro-plating layer pattern 118C formed in the same process may have different thicknesses. That is, the thickness of the first circuit electro-plating layer pattern 118C may be greater than the thickness of the first pad electro-plating layer pattern 118P.

According to the circuit board according to the above-described embodiment, circuit design constraints due to the metal thickness of the circuit layer are reduced, and a fine circuit pattern may be implemented.

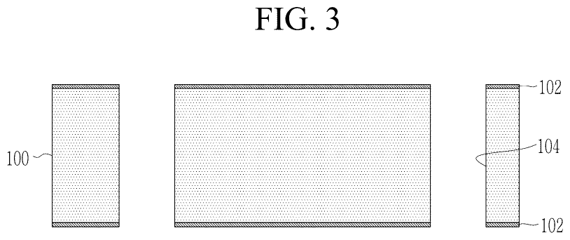

Hereinafter, a manufacturing method of the circuit board 10A according to an embodiment will be described with reference to FIG. 3 to FIG. 14.

FIG. 3 to FIG. 14 are cross-sectional views illustrating a manufacturing method of a circuit board according to an embodiment.

Referring to FIG. 3, the first insulating layer 100 having a copper foil layer 102 formed on both surfaces thereof may be prepared. The copper foil layer 102 may be formed by stacking and pressing a copper foil on both surfaces of the first insulating layer 100. The via hole 104 may be formed to penetrate the first insulating layer 100 and the copper foil layer 102. The via hole 104 may be formed in plural by laser processing, mechanical drill processing, or the like.

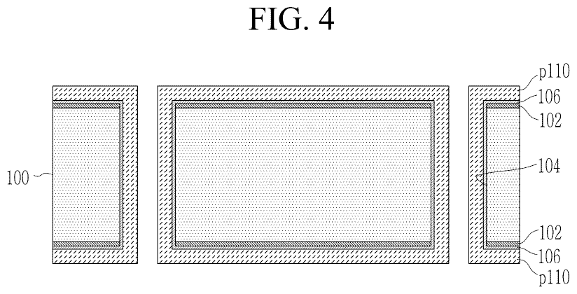

Referring to FIG. 4, a first seed layer 106 may be formed on a surface of the first insulating layer 100 having the via hole 104. The first seed layer 106 may be formed on the copper foil layer 102 and on the inner wall of the via hole 104. The first seed layer 106 may be formed as a copper layer by electroless plating.

A through via forming portion p110 may be formed on the first seed layer 106. The through via forming portion p110 may be formed on the first seed layer 106. The through via forming portion p110 may be formed by electro-plating on the first seed layer 106 and may be formed of copper.

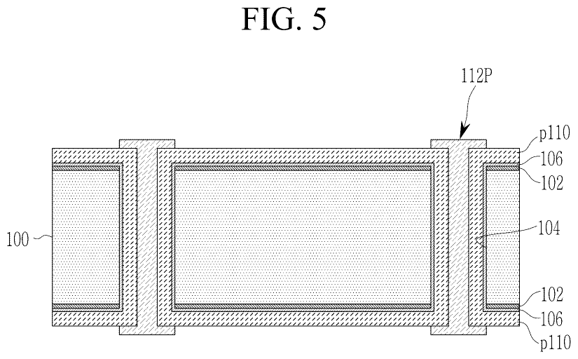

Referring to FIG. 5, a preliminary plug 112P may be formed to fill the inside of the via hole 104 in which the through via forming portion p110 is formed, and to extend to at least one surface of the through via forming portion p110. The preliminary plug 112P may be formed by printing an insulating ink.

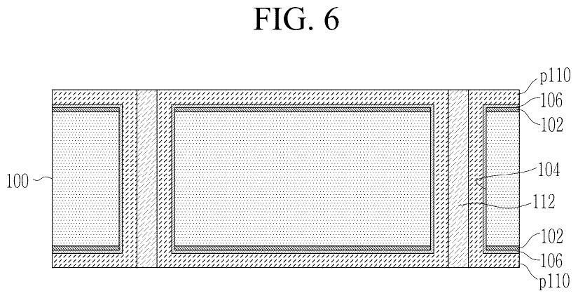

Referring to FIG. 6, the preliminary plug 112P of the portion formed on the through via forming portion p110 and a portion of the through via forming portion p110 may be polished to planarize the surfaces thereof. In this process, the preliminary plug 112P of the portion extending onto the through via forming portion p110 may be removed to form the plug 112. In addition, the surfaces of the plug 112 and the through via forming portion p110 may be positioned on substantially the same plane. The plug 112 may be surrounded by the through via forming portion p110. The plug 112 may be formed of non-conductive material.

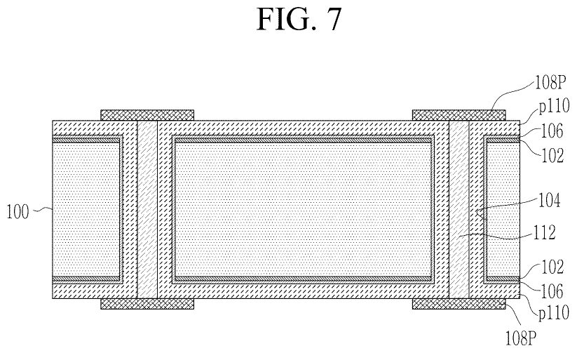

Referring to FIG. 7, a first mask pattern 108P exposing the first seed layer 106 around the via hole 104 may be formed on the through via forming portion p110. The first mask pattern 108P may expose a region positioned along the edge of the via hole 104 on the through via forming portion p110. The first mask pattern 108P may be patterned by exposing and developing a photosensitive dry film.

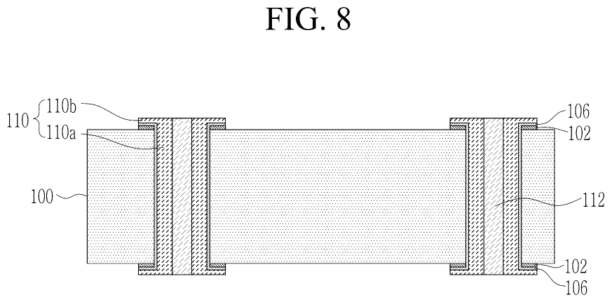

Referring to FIG. 7 and FIG. 8, the through via forming portion p110, the first seed layer 106, and the copper foil layer 102 of a region exposed by the first mask pattern 108P may be etched. Therefore, the through via 110 may be formed on the copper foil layer 102 and the first seed layer 106 covered by the first mask pattern 108P. The through via 110 may include the penetrating portion 110a on the inner wall of the via hole 104, and the extending portion 110b connected to the penetrating portion 110a and extending onto upper and lower surfaces of the first insulating layer 100. The through via 110 may be formed by using the first mask pattern 108P as an etching resist. After etching, the first mask pattern 108P may be peeled off and removed.

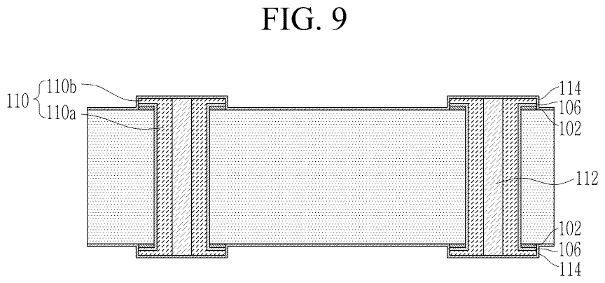

Referring to FIG. 9, a second seed layer 114 may be formed on the copper foil layer 102, the first seed layer 106, the extending portion 110b of the through via 110, and the plug 112. The second seed layer 114 may be formed of a copper layer through electroless plating.

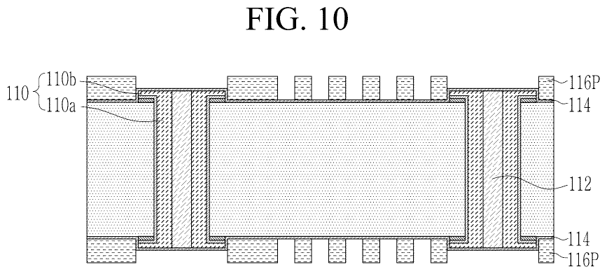

Referring to FIG. 10, a second mask pattern 116P may be formed on the second seed layer 114. The second mask pattern 116P may continuously expose the second seed layer 114 on the plug 112 and the second seed layer 114 on at least a portion of the extending portion 110b. In addition, the second mask pattern 116P may expose the second seed layer 114 of a region where a circuit wiring is to be formed in a later process. The second mask pattern 116P may be patterned by exposing and developing a photosensitive dry film.

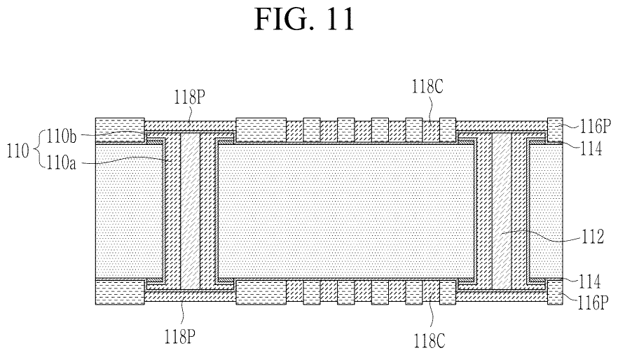

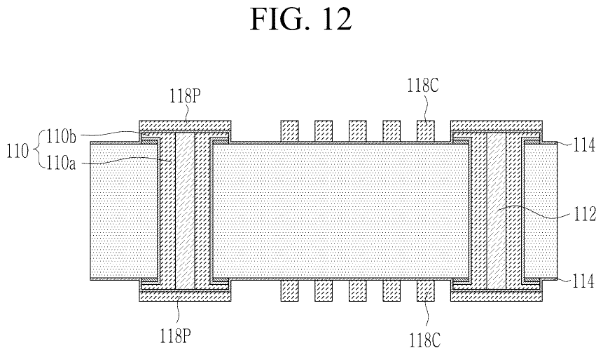

Referring to FIG. 11 and FIG. 12, the first pad electro-plating layer pattern 118P and the first circuit electro-plating layer pattern 118C may be formed on the exposed second seed layer 114 by using the second mask pattern 116P as a plating mask. The first pad electro-plating layer pattern 118P and the first circuit electro-plating layer pattern 118C may be formed of copper layer. Then, the second mask pattern 116P may be peeled off and removed.

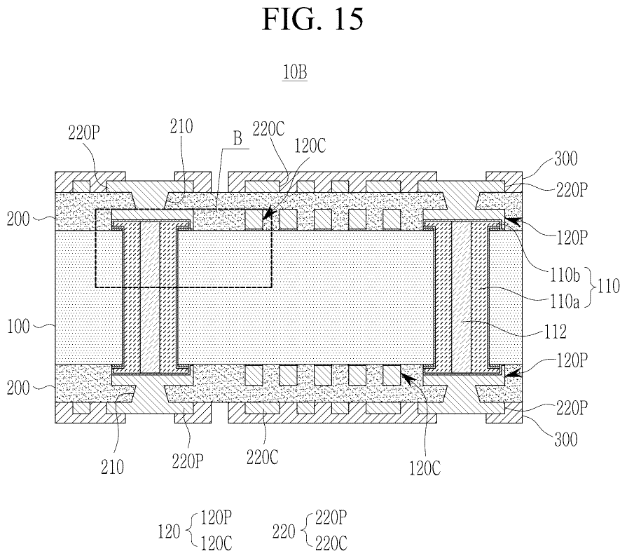

Meanwhile, when the second mask pattern 116P of FIG. 10 is formed to be partially or completely spaced apart from the second seed layer 114 formed on the sidewall of the extending portion 110b, the first pad electro-plating layer pattern 118P may be formed to partially or completely cover the second seed layer 114 formed on the sidewall of the extending portion 110b (see FIG. 15).

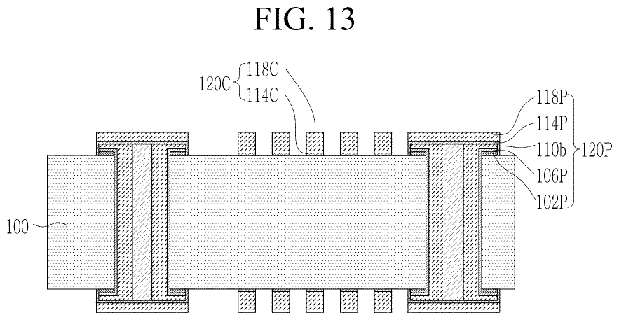

Referring to FIG. 13, after removing the second mask pattern 116P, the exposed second seed layer 114 may be removed to form the first pad 120P and the first circuit wiring 120C.

As a result, the first pad 120P may include the first pad copper foil layer pattern 102P, the first pad seed layer pattern 106P, the extending portion 110b of the through via 110, the second pad seed layer pattern 114P, and the first pad electro-plating layer pattern 118P, which are sequentially stacked on the first insulating layer 100. The first circuit wiring 120C may include a second circuit seed layer pattern 114C and the first circuit electro-plating layer pattern 118C, which are sequentially stacked on the first insulating layer 100. The first pad 120P may include two electro-plating layers of the extending portion 110b and the first pad electro-plating layer pattern 118P, while the first circuit wiring 120C may include one electro-plating layer of the first circuit electro-plating layer pattern 118C. In addition, the first pad 120P may be formed such that an electro-plating layer is interposed between two electroless plating layers, while the first circuit wiring 120C may be formed to include one electroless plating layer.

Meanwhile, the exposed second seed layer 114 may be removed through wet etching using a chemical solution, and depending on the degree or method of etching, the second seed layer 114 on the sidewall of the extending portion 110b may be partially or entirely removed. For example, if the chemical solution is sprayed in a vertical direction in the stacking direction, the second seed layer 114 on the sidewall of the extending portion 110b may partially remain.

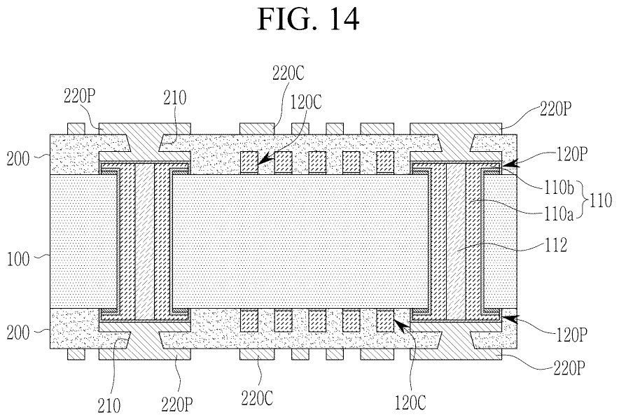

Referring to FIG. 14, the second insulating layer 200 may be formed on the first insulating layer 100 so that the first pad 120P and the first circuit wiring 120C are buried. Furthermore, the second pad 220P and the second circuit wiring 220C may be formed on the second insulating layer 200. In addition, a build up via 210 may be formed to connect the first pad 120P and the second pad 220P through the second insulating layer 200. The second pad 220P, the second circuit wiring 220C, and the build up via 210 may be formed by performing a conventional wiring process, such as a subtractive process, an Additive Process (AP), a Semi Additive Process (SAP), or a Modified Semi Additive Process (MSAP).

Referring to FIG. 12 and FIG. 1, the passivation layer 300 exposing a portion of the second pad 220P may be formed on the second insulating layer 200 on which the second pad 220P and the second circuit wiring 220C are formed. The passivation layer 300 may be a solder resist layer formed by exposing and developing a photosensitive resin.

According to the embodiment of the manufacturing of the circuit board, by forming a circuit layer using an SAP process, it is possible to reduce circuit design constraints due to the metal thickness of the circuit layer without affecting the formation of through vias and plugs, and to miniaturize the circuit.

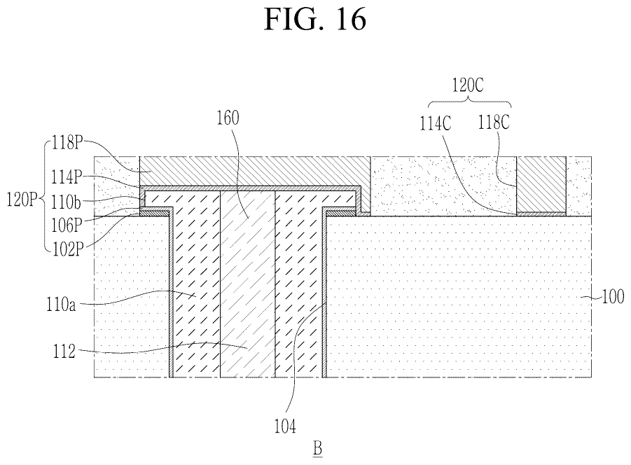

Hereinafter, A circuit board 10B according to another embodiment will be described with reference to FIG. 15 and FIG. 16.

FIG. 15 is a cross-sectional view schematically illustrating a circuit board according to another embodiment. FIG. 16 is an enlarged cross-sectional view of portion B of the circuit board illustrated in FIG. 15.

Referring to FIG. 15 and FIG. 16, the circuit board 10B according to another embodiment is similar to the circuit board 10A according to the embodiment described with reference to FIG. 1 to FIG. 14. Detailed description of the same elements is omitted.

Referring to FIG. 15 and FIG. 16, unlike the circuit board 10A according to the embodiment illustrated in FIG. 1 and FIG. 2, the second pad seed layer pattern 114P and the first pad electro-plating layer pattern 118P of the circuit board 10B of another embodiment may be disposed to have a step difference at one end thereof in the. The second pad seed layer pattern 114P may include a portion that does not overlap the extending portion 110b in the stacking direction. The first pad electro-plating layer pattern 118P may include a portion that does not overlap the extending portion 110b in the stacking direction. The first pad electro-plating layer pattern 118P may be disposed to expose a portion of the second pad seed layer pattern 114P from the first pad electro-plating layer pattern 118P at one end thereof, and cover another portion of the second pad seed layer pattern 114P at the other end thereof.

Unlike the manufacturing method of the circuit board 10A according to the embodiment of FIG. 10, centers of the extending portion 110b and the opened region of the second mask pattern 116P may not coincide with each other, and a portion of the second mask pattern 116P may be formed to overlap the extending portion 110b in the stacking direction. Therefore, the second pad seed layer pattern 114P and the first pad electro-plating layer pattern 118P may be formed by plating the opened region of the second mask pattern 116P to have a step difference from the extending portion 110b. The second pad seed layer pattern 114P may be formed to extend onto the first pad seed layer pattern 106P at one end thereof. The first pad electro-plating layer pattern 118P may be formed to cover the second pad seed layer pattern 114P extending from one end onto the first pad seed layer pattern 106P.

According to the circuit board and the manufacturing method thereof according to another embodiment, circuit design constraints due to the metal thickness of the circuit layer can be reduced and circuit miniaturization is possible by forming the extending portion of the through via and the circuit layer through a separate plating process rather than simultaneously forming a single plating process.

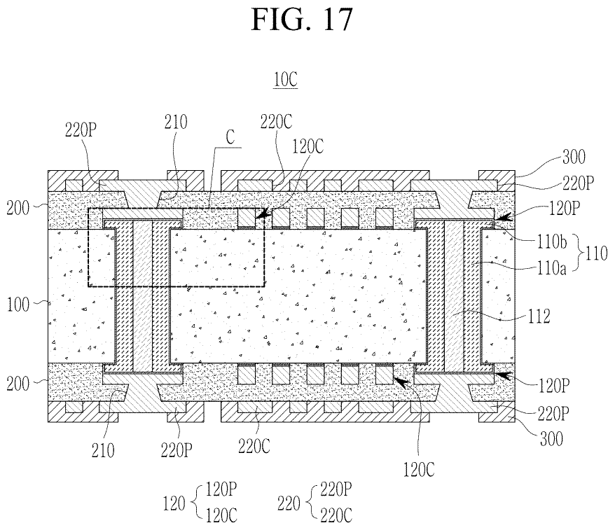

Hereinafter, a circuit board 10C and a manufacturing method thereof according to yet another embodiment will be described with reference to FIG. 17 to FIG. 29.

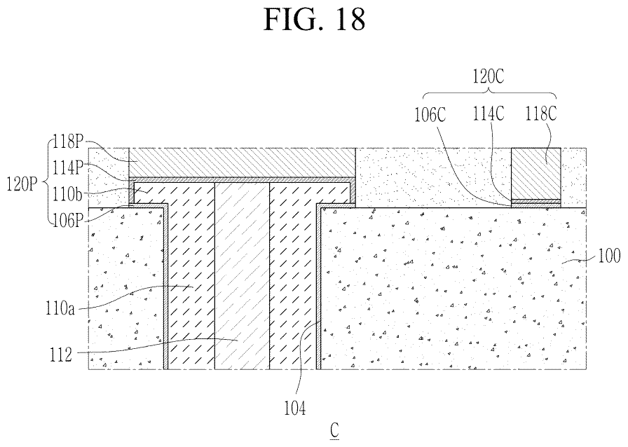

FIG. 17 is a cross-sectional view schematically illustrating a circuit board according to yet another embodiment. FIG. 18 is an enlarged cross-sectional view of portion C of the circuit board illustrated in FIG. 17.

Referring to FIG. 17 and FIG. 18, the circuit board 10C according to yet another embodiment is similar to the circuit board 10A according to the embodiment described with reference to FIG. 1 to FIG. 14. Detailed description of the same elements is omitted.

Referring to FIGS. 17 and 18, the circuit board 10C according to yet another embodiment may have a glass core, unlike the circuit board 10A according to the embodiment illustrated in FIG. 1 and FIG. 2. The glass core may include, for example, pure silicon dioxide (about 100% SiO2), soda lime glass, borosilicate glass, alumino-silicate glass, etc., and is not limited to the above silicon-based glass compositions, and alternative glass materials such as fluorine glass, phosphate glass, chalcogen glass, etc. may also be used. In addition, other additives may be further included to form glass with specific physical properties. These additives can include calcium carbonate (e.g., lime) and sodium carbonate (e.g., soda), as well as magnesium, calcium, manganese, aluminum, lead, boron, iron, chromium, potassium, sulfur, and antimony, as well as carbonates and/or oxides of these and other elements.

Furthermore, referring to FIG. 17 and FIG. 18, the circuit board 10C according to yet another embodiment may not include the first pad copper foil layer pattern 102P, unlike the circuit board 10A according to the embodiment illustrated in FIG. 1 and FIG. 2. Therefore, the first pad 120P of the circuit board 10C according to yet another embodiment may include the first pad seed layer pattern 106P, the extending portion 110b of the through via 110, the second pad seed layer pattern 114P, and a first pad electro-plating layer pattern 118P, which are sequentially stacked on the first insulating layer 100.

In addition, the circuit board 10C according to yet another embodiment may include the first circuit seed layer pattern 106C disposed on the first insulating layer 100, unlike the circuit board 10A according to the embodiment illustrated in FIG. 1 and FIG. 2. The first circuit seed layer pattern 106C may be interposed between the first insulating layer 100 and the second circuit seed layer pattern 114C. Therefore, the first circuit wiring 120C of the circuit board 10C according to yet another embodiment may include the first circuit seed layer pattern 106C, the second circuit seed layer pattern 114C, and the first circuit electro-plating layer pattern 118C, which are sequentially stacked on the first insulating layer 100.

The first pad 120P may include two electro-plating layers of the extending portion 110b and the first pad electro-plating layer pattern 118P, while the first circuit wiring 120C may include one electro-plating layer of first circuit electro-plating layer pattern 118C. In addition, the first pad 120P may be formed such that an electro-plating layer is interposed between two electroless plating layers, while the first circuit wiring 120C may be formed to include two electroless plating layers that are in direct contact with each other as a whole.

According to the circuit board according to yet another embodiment described above, by using a glass core, it is possible to provide a circuit board having high rigidity and little deformation. In addition, circuit design constraints due to the metal thickness of the circuit layer are reduced and miniaturized circuit patterns can be implemented.

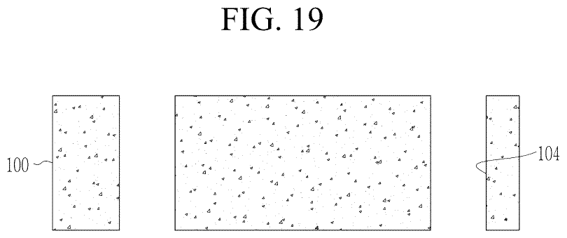

FIG. 19 to FIG. 29 are cross-sectional views illustrating a manufacturing method of a circuit board according to yet another embodiment.

Referring to FIG. 19, the first insulating layer 100, which is a glass core, may be provided. The glass core may include, for example, pure silicon dioxide (about 100% SiO2), soda lime glass, borosilicate glass, alumino-silicate glass, etc., and is not limited to the above silicon-based glass compositions, and alternative glass materials such as fluorine glass, phosphate glass, chalcogen glass, etc. may also be used. In addition, other additives may be further included to form glass with specific physical properties. These additives can include calcium carbonate (e.g., lime) and sodium carbonate (e.g., soda), as well as magnesium, calcium, manganese, aluminum, lead, boron, iron, chromium, potassium, sulfur, and antimony, as well as carbonates and/or oxides of these and other elements.

In addition, referring to FIG. 19, the via hole 104 penetrating the first insulating layer 100 may be formed. The via hole 104 may be formed in plural by laser processing, mechanical drill processing, or the like.

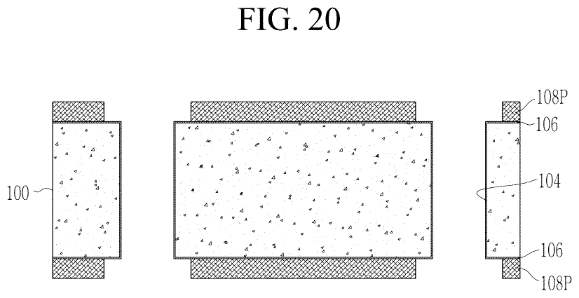

Referring to FIG. 20, the first seed layer 106 may be formed on a surface of the first insulating layer 100 having the via hole 104. The first seed layer 106 may be formed on the first insulating layer 100 and on the inner wall of the via hole 104. The first seed layer 106 may be formed as a copper layer through electroless plating. The first mask pattern 108P exposing the via hole 104 and the first seed layer 106 around the via hole 104 may be formed on the first seed layer 106. The first mask pattern 108P may expose a region positioned along an edge of the via hole 104 on the first seed layer 106. The first mask pattern 108P may be patterned by exposing and developing a photosensitive dry film.

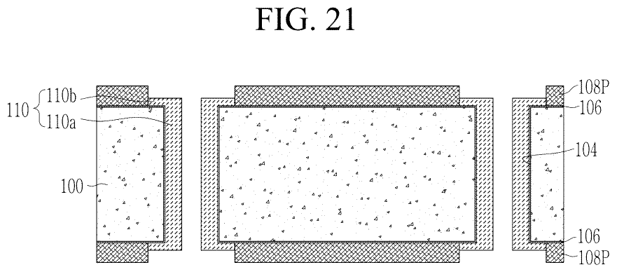

Referring to FIG. 21, the through via 110 may be formed on the first seed layer 106 exposed by the first mask pattern 108P. The through via 110 may be formed by plating a region exposed by the first mask pattern 108P and the inner wall of the via hole 104. The through via 110 may include the penetrating portion 110a on the inner wall of the via hole 104, and the extending portion 110b connected to the penetrating portion 110a and extending onto upper and lower surfaces of the first insulating layer 100. The through via 110 may be formed by electro-plating on the exposed first seed layer 106 using the first mask pattern 108P as a plating mask, and may be formed of copper.

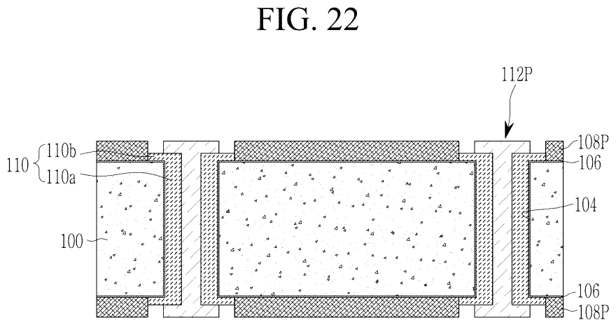

Referring to FIG. 22, the preliminary plug 112P which fills the inside of the via hole 104 in which the through via 110 is formed and extends onto the extending portion 110b may be formed. The preliminary plug 112P may be formed by printing an insulating ink.

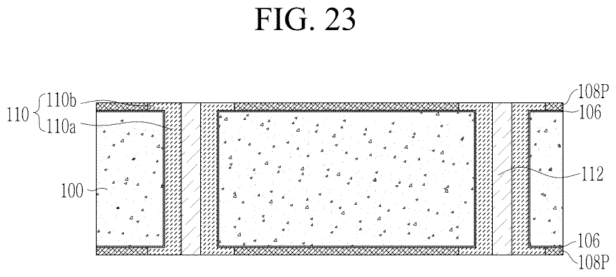

Referring to FIG. 23, the preliminary plug 112P of the portion formed on the extending portion 110b of the through via 110, the extending portion 110b of the through via 110, and the first mask pattern 108P may be polished to planarize the surfaces thereof. In this process, the preliminary plug 112P of the portion extending onto the extending portion 110b may be removed to form the plug 112. In addition, the thicknesses of the extending portion 110b and the first mask pattern 108P may be reduced, and the surfaces of the plug 112, the extending portion 110b, and the first mask pattern 108P may be positioned on substantially the same plane. The plug 112 may be surrounded by the penetrating portion 110a of the through via 110. The plug 112 may be formed of non-conductive material.

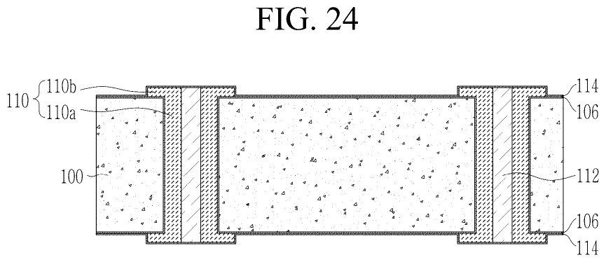

Referring to FIG. 24, after peeling off and removing the remaining first mask pattern 108P, the second seed layer 114 may be formed on the first seed layer 106, the extending portion 110b of the through via 110, and the plug 112. The second seed layer 114 may be formed of a copper layer through electroless plating.

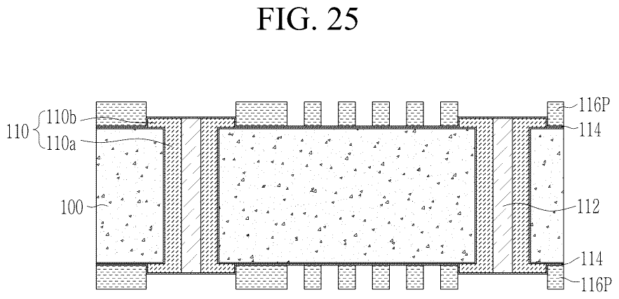

Referring to FIG. 25, the second mask pattern 116P may be formed on the second seed layer. The second mask pattern 116P may continuously expose the second seed layer 114 on the plug 112 and the second seed layer 114 on at least a portion of the extending portion 110b. Furthermore, the second mask pattern 116P may expose the second seed layer 114 of a region where a circuit wiring is to be formed in a later process, which is located on a portion of the first insulating layer 100. The second mask pattern 116P may be patterned by exposing and developing a photosensitive dry film.

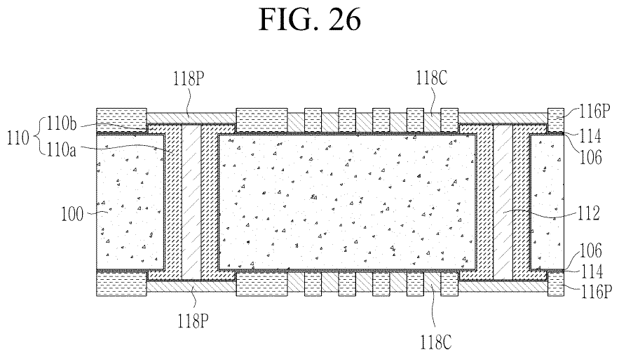

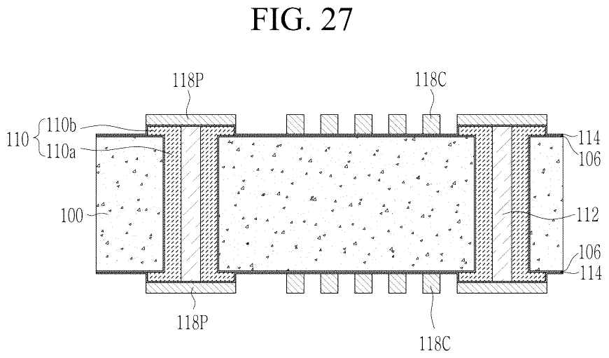

Referring to FIG. 26 and FIG. 27, the first pad electro-plating layer pattern 118P and the first circuit electro-plating layer pattern 118C may be formed on the exposed second seed layer 114 by using the second mask pattern 116P as a plating mask. The first pad electro-plating layer pattern 118P and the first circuit electro-plating layer pattern 118C may be formed of copper layer. Then, the second mask pattern 116P may be peeled off and removed.

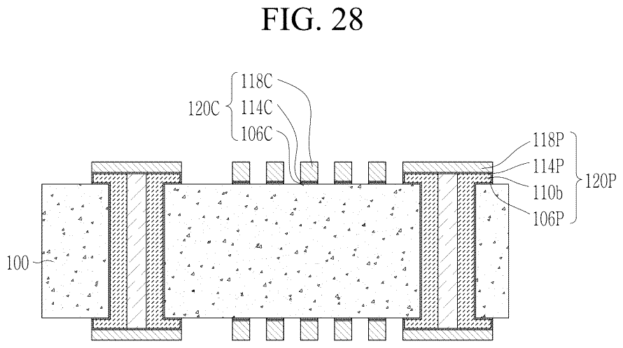

Referring to FIG. 28, the first pad 120P and the first circuit wiring 120C may be formed by removing the exposed second seed layer 114 and the first seed layer 106 below the second seed layer 114 after removing the second mask pattern 116P.

As a result, the first pad 120P may include the first pad seed layer pattern 106P, the extending portion 110b of the through via 110, the second pad seed layer pattern 114P, and the first pad electro-plating layer pattern 118P, which are sequentially stacked on the first insulating layer 100. The first circuit wiring 120C may include the first circuit seed layer pattern 106C, the second circuit seed layer pattern 114C, and the first circuit electro-plating layer pattern 118C, which are sequentially stacked on the first insulating layer 100. The first pad 120P may include two electro-plating layers of the extending portion 110b and the first pad electro-plating layer pattern 118P, while the first circuit wiring 120C may include one electro-plating layer of the first circuit electro-plating layer pattern 118C. In addition, the first pad 120P may be formed such that an electro-plating layer is interposed between two electroless plating layers, while the first circuit wiring 120C may be formed to include two electroless plating layers that are in direct contact with each other as a whole.

Meanwhile, the exposed second seed layer 114 and the first seed layer 106 below the second seed layer 114 may be removed through wet etching using a chemical solution, and depending on the degree or method of etching, the second seed layer 114 on the sidewall of the extending portion 110b may be partially or entirely removed. For example, if the chemical solution is sprayed in a vertical direction in the stacking direction, the second seed layer 114 on the sidewall of the extending portion 110b may partially remain.

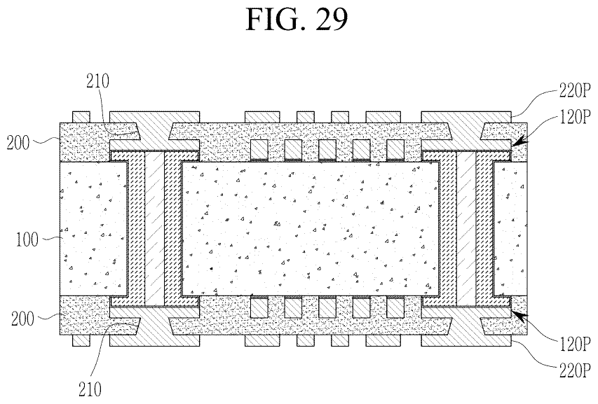

Referring to FIG. 29, the second insulating layer 200 may be formed on the first insulating layer 100 so that the first pad 120P and the first circuit wiring 120C are buried. Furthermore, the second pad 220P and the second circuit wiring 220C may be formed on the second insulating layer 200. In addition, a build up via 210 may be formed to connect the first pad 120P and the second pad 220P through the second insulating layer 200. The second pad 220P, the second circuit wiring 220C, and the build up via 210 may be formed by performing a conventional wiring process, such as a subtractive process, an Additive Process (AP), a Semi Additive Process (SAP), or a Modified Semi Additive Process (MSAP).

Referring to FIG. 29 and FIG. 17, the passivation layer 300 exposing a portion of the second pad 220P may be formed on the second insulating layer 200 on which the second pad 220P and the second circuit wiring 220C are formed. The passivation layer 300 may be a solder resist layer formed by exposing and developing a photosensitive resin.

According to yet another embodiment of the manufacturing method of a circuit board, the through via can be formed more finely and precisely by forming a mask layer on the insulating layer and then forming a through via.

In addition, by using a glass core, the manufacturing method of the circuit board with high rigidity and less deformation can be provided. Furthermore, circuit design constraints due to the metal thickness of the circuit layer are reduced and miniaturized circuit patterns can be implemented.

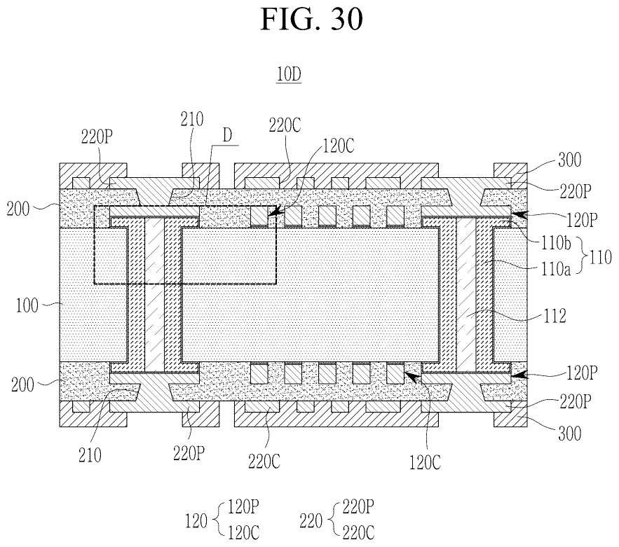

Hereinafter, a circuit board 10D and a manufacturing method thereof according to yet another embodiment will be described with reference to FIG. 30 to FIG. 32.

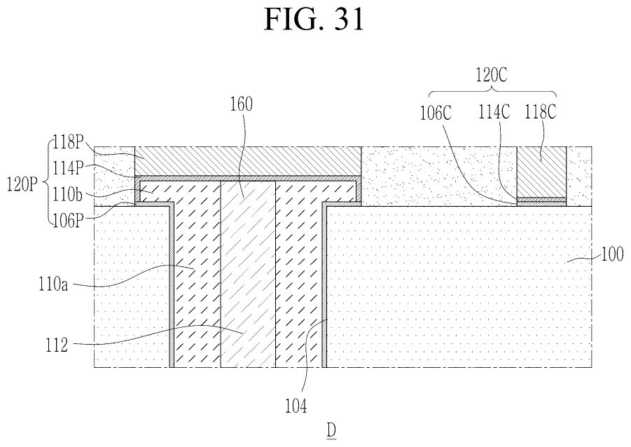

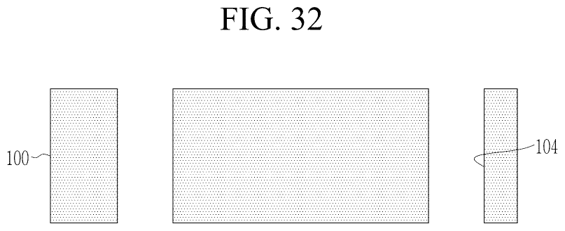

FIG. 30 is a cross-sectional view schematically illustrating a circuit board according to yet another embodiment. FIG. 31 is an enlarged cross-sectional view of portion D of the circuit board illustrated in FIG. 30. FIG. 32 is a cross-sectional view for explaining the manufacturing method of the circuit board illustrated in FIG. 30.

Referring to FIG. 30 and FIG. 31, the circuit board 10D according to yet another embodiment is similar to the circuit board 10A according to the embodiment described with reference to FIG. 1 to FIG. 14. Detailed description of the same elements is omitted.

Referring to FIG. 30 and FIG. 31, the circuit board 10D according to yet another embodiment may not include the first pad copper foil layer pattern 102P, unlike the circuit board 10A according to the embodiment illustrated in FIG. 1 and FIG. 2. Therefore, the first pad 120P of the circuit board 10D according to yet another embodiment may include the first pad seed layer pattern 106P, the extending portion 110b of the through via 110, the second pad seed layer pattern 114P, and the first pad electro-plating layer pattern 118P.

In addition, the circuit board 10D according to yet another embodiment may include the first circuit seed layer pattern 106C disposed on the first insulating layer 100, unlike the circuit board 10A according to the embodiment illustrated in FIG. 1 and FIG. 2. The first circuit seed layer pattern 106C may be interposed between the first insulating layer 100 and the second circuit seed layer pattern 114C. Therefore, the first circuit wiring 120C of the circuit board 10D according to yet another embodiment may include the first circuit seed layer pattern 106C, the second circuit seed layer pattern 114C, and the first circuit electro-plating layer pattern 118C, which are sequentially stacked on the first insulating layer 100.

The first pad 120P may include two electro-plating layers of the extending portion 110b and the first pad electro-plating layer pattern 118P, while the first circuit wiring 120C may include one electro-plating layer of first circuit electro-plating layer pattern 118C. In addition, the first pad 120P may be formed such that an electro-plating layer is interposed between two electroless plating layers, while the first circuit wiring 120C may be formed to include two electroless plating layers that are in direct contact with each other as a whole.

According to the circuit board according to yet another embodiment, circuit design constraints due to the metal thickness of the circuit layer can be reduced and circuit miniaturization is possible without affecting the formation of the through via and the plug by simultaneously forming the through via and the circuit layer through a separate plating process.

A manufacturing method of the circuit board 10D in accordance with yet another embodiment is similar to the manufacturing method of the circuit board 10C in accordance with yet another embodiment described with reference to FIG. 19 to FIG. 29. Detailed description of the same elements is omitted.

Referring to FIG. 30 to FIG. 32, unlike the manufacturing method of the circuit board 10C according to yet another embodiment illustrated in FIG. 19 to FIG. 29, the manufacturing method of the circuit board 10D according to yet another embodiment may prepare the first insulating layer 100 with the copper foil layer 102 formed on both surfaces thereof and remove the copper foil layer 102 disposed on the first insulating layer 100. Specifically, as illustrated in FIG. 3, a first insulating layer 100 in which the copper foil layer 102 is formed on both surfaces may be prepared. Thereafter, as illustrated in FIG. 32, the copper foil layer 102 positioned on the first insulating layer 100 may be etched and removed. The etching process may use dry etching or wet etching, but is not limited thereto. Surface roughness may be formed on both surfaces of the first insulating layer 100 from which the copper foil layer 102 is removed.

In addition, according to yet another embodiment of the manufacturing method of the circuit board 10D, the first insulating layer 100 may not be a glass core, unlike the manufacturing method of the circuit board 10C according to yet another embodiment illustrated in FIG. 19 to FIG. 29. According to yet another embodiment of the manufacturing method of the circuit board 10D, the first insulating layer 100 may include insulating material. The insulating material may include a thermosetting resin such as an epoxy resin, a thermoplastic resin such as polyimide, or these resins containing an inorganic filler such as silica and a reinforcing material such as glass fiber. The insulating material may be a photosensitive material or a non-photosensitive material. For example, solder resist (SR), ajinomoto-build up film (ABF), FR-4, Bismaleimide Triazine (BT), resin coated copper (RCC) or copper clad laminate (CCL), etc. may be used as the insulating material, but are not limited thereto. The insulating material may include a polymer material. For example, a prepreg may be used, but is not limited thereto.

According to the manufacturing method of a circuit board in accordance with yet another embodiment, the through via can be formed more finely and elaborately by forming a mask layer on the insulating layer and then forming a through via.

In addition, according to yet another embodiment of the manufacturing method of the circuit, by forming a circuit layer using the SAP method, it is possible to reduce circuit design constraints due to the metal thickness of the circuit layer without affecting the formation of through vias and plugs, and to miniaturize the circuit.

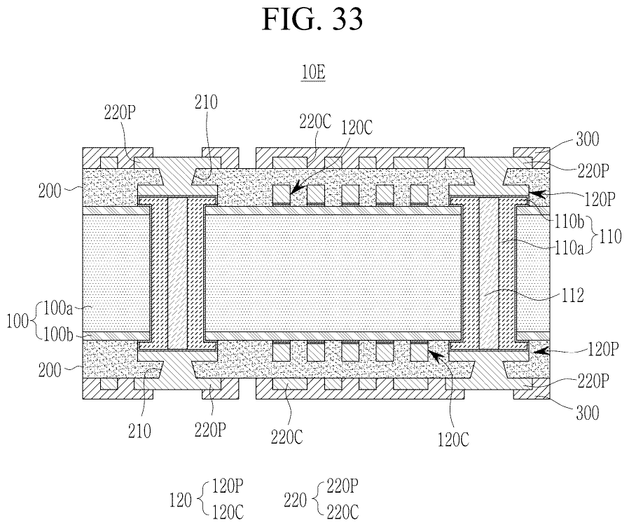

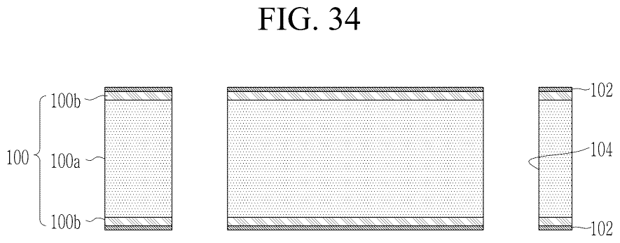

Hereinafter, A circuit board 10E according to yet another embodiment will be described with reference to FIG. 33 and FIG. 34.

FIG. 33 is a cross-sectional view schematically illustrating a circuit board according to yet another embodiment. FIG. 34 is a cross-sectional view for explaining the manufacturing method of the circuit board illustrated in FIG. 33.

Referring to FIG. 33, the circuit board 10E according to yet another embodiment is similar to the circuit board 10A according to the embodiment described with reference to FIG. 1 to FIG. 2. Detailed description of the same elements is omitted.

Referring to FIG. 33, unlike the circuit board 10A according to an embodiment illustrated in FIG. 1 and FIG. 2, according to yet another embodiment of the circuit board 10E, the first insulating layer 100 may include a core portion 100a and a primer layer 100b stacked on opposite both surfaces of the core portion 100a.

An insulating material may be used as the material of the core portion 100a. In this case, the insulating material may be a thermosetting resin such as an epoxy resin, a thermoplastic resin such as polyimide, and a material including a reinforcing material such as an inorganic filler and/or glass fiber, for example, a prepreg. The primer layer 100b may be a layer capable of electrical insulation and may be a layer capable of easily forming a microcircuit pattern due to high plating adhesion due to easily forming roughness. For example, the primer layer 100b may be formed of an acrylic resin, acrylic urethane, epoxy resin, or a mixture of two or more of them, but is not limited thereto.

Referring to FIG. 34, a manufacturing method of the circuit board 10E in accordance with yet another embodiment is similar to the manufacturing method of the circuit board 10C in accordance with yet another embodiment described with reference to FIG. 19 to FIG. 29. Detailed description of the same elements is omitted.

Referring to FIG. 34, the manufacturing method of the circuit board 10E according to yet another embodiment may include forming the core portion 100a and forming the first insulating layer 100 by stacking the primer layer 100b on opposite both surfaces of the core portion 100a, unlike the manufacturing method of the circuit board 10C according to yet another embodiment described with reference to FIG. 19 to FIG. 29.

Specifically, referring to FIG. 34, the primer layer 100b may be formed on both surfaces of the core portion 100a. In addition, the copper foil layer 102 may be formed by stacking and pressing a copper foil on the primer layer 100b.

In addition, the via hole 104 may be formed through the first insulating layer 100 and the copper foil layer 102. The via hole 104 may be formed in plural by laser processing, mechanical drill processing, or the like.

Thereafter, as described with reference to FIG. 19 to FIG. 29, the copper foil layer 102 may be etched and removed, and the above-described process may proceed.

According to the manufacturing a method of the circuit board according to yet another embodiment, the insulating layer and the circuit layer are formed on the primer layer to improve plating adhesion, thereby easily forming a microcircuit pattern. In addition, by forming the extending portion of the through via and the circuit layer through a separate plating process rather than simultaneously forming through a single plating process, circuit design constraints due to the metal thickness of the circuit layer can be reduced and circuit miniaturization can be made without affecting the formation of through vias and plugs.

While embodiments of the present disclosure have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A circuit board comprising;
an insulating layer having a via hole penetrating in a first direction;
a through via extending to fill the via hole and having a hollow portion penetrating in the first direction;
a plug disposed to fill the hollow portion of the through via; and
a circuit layer disposed on the insulating layer and the through via,
wherein the through via comprises a penetrating portion extending in the first direction and an extending portion extending from the penetrating portion in a direction perpendicular to the first direction and disposed on the insulating layer, and
the circuit layer comprises a pad disposed on the extending portion and a circuit wiring disposed on the insulating layer.

2. The circuit board of claim 1, wherein:
the circuit layer comprises an electroless plating layer disposed on the through via and the insulating layer, and an electro-plating layer disposed on the electroless plating layer.

3. The circuit board of claim 2, wherein:
a portion of the electroless plating layer disposed on the through via covers at least a side surface of the extending portion.

4. The circuit board of claim 2, wherein:
a portion of the electroless plating layer disposed on the through via extends along an outer circumferential surface of the extending portion.

5. The circuit board of claim 1, wherein:
the pad comprises a first pad seed layer pattern, the extending portion of the through via, a second pad seed layer pattern, and a first pad electro-plating layer pattern, which are sequentially stacked on the insulating layer.

6. The circuit board of claim 5, wherein:
the circuit wiring comprises a second circuit seed layer pattern, and a first circuit electro-plating layer pattern.

7. The circuit board of claim 6, wherein:
the thickness of the first circuit electro-plating layer pattern is greater than that of the first pad electro-plating layer pattern.

8. The circuit board of claim 5, further comprising:
a first pad copper foil layer pattern disposed between the insulating layer and the first pad seed layer pattern in the first direction.

9. The circuit board of claim 5, wherein:
the second pad seed layer pattern is disposed to have a step at one end.

10. The circuit board of claim 9, wherein:
the first pad electro-plating layer pattern is disposed to have a step at one end.

11. The circuit board of claim 1, wherein:
the plug protrudes from a surface of the insulating layer.

12. The circuit board of claim 1, wherein:
the plug is non-conductive.

13. The circuit board of claim 1, wherein:
the insulating layer comprises a core portion and a primer layer stacked on opposite sides of the core portion.

14. The circuit board of claim 1, wherein:
the insulating layer comprises a glass core.

15. A manufacturing method of a circuit board, comprising:
stacking a copper foil on a surface of an insulating layer to form a copper foil layer,
forming a via hole to penetrate the insulating layer and the copper foil layer,
plating on the copper foil layer and an inner wall of the via hole to form a through via forming portion,
forming a plug to fill an inner space of the through via forming portion,
forming a first mask pattern at a region disposed along an edge of the via hole on the through via forming portion,
etching an exposed portion by the first mask pattern to form a through via,
forming a second mask pattern to expose a region disposed on the through via and the plug, and a region disposed on a portion of the insulating layer spaced apart from the region on the through via, and
forming a circuit layer by plating on the regions exposed by the second mask pattern.

16. The manufacturing method of claim 15, further comprising:
forming a first seed layer by electroless plating on a surface of the insulating layer in which the via hole is formed,
wherein forming the through via forming portion comprises electro-plating on the first seed layer to form the through via forming portion.

17. The manufacturing method of claim 15, wherein:
forming the circuit layer comprises plating on the regions exposed by the second mask pattern to have a step with a portion of the through via disposed on the insulating layer.

18. A manufacturing method of a circuit board, comprising:
forming a via hole to penetrate an insulating layer,
forming a third mask pattern on the insulating layer to expose a region disposed along an edge of the via hole,
plating along the exposed region and an inner wall of the via hole to form a through via,
forming a plug to fill an inner space of the through via,
forming a fourth mask pattern to expose a region disposed on the through via and the plug, and a region disposed on a portion of the insulating layer, and
plating on the regions exposed by the fourth mask pattern to form a circuit layer.

19. The manufacturing method of claim 18, wherein:
forming the circuit layer comprises forming an electroless plating layer, and forming an electro-plating layer on the electroless plating layer.

20. The manufacturing method of claim 18, further comprising:
forming a core portion, and
stacking a primer layer on opposite sides of the core portion to form the insulating layer.

21. The manufacturing method of claim 18, wherein:
the insulating layer comprises a glass core.

22. The manufacturing method of claim 18, further comprising:
stacking a copper foil on a surface of the insulating layer to form a copper foil layer, and
removing the copper foil layer by etching.

23. The manufacturing method of claim 15,
wherein the insulating layer comprises a core portion, and a primer layer disposed on opposite surfaces of the core portion.
